(19) United States
(12) Patent Application Publication
(10) Pub. No.: US 2015/0100256 A1
(43) Pub. Date: Apr. 9, 2015

(54) IMBALANCE DETERMINING METHOD, IMBALANCE DETERMINING APPARATUS, AND RECORDING MEDIUM

(71) Applicant: FUJITSU Limited, Kawasaki-shi (JP)

(72) Inventors: Tetsuya KASHIWAGI, Fukuoka (JP); Yuichi MATSUFUJI, Fukuoka (JP)

(21) Appl. No.: 14/499,756

(22) Filed: Sep. 29, 2014

(30) Foreign Application Priority Data
Oct. 9, 2013 (JP) 2013-211945

(51) Int. Cl. G01R 25/00; H02H 3/353

(52) U.S. Cl. CPC G01R 25/005; H02H 3/353
USPC 702/59

(57) ABSTRACT

A non-transitory computer-readable recording medium has stored therein a program that causes a computer to execute an imbalance determining process. The imbalance determining process includes: analyzing fluctuation situations of voltage values of respective phases in a power distribution line using a three-phase three-wire system; determining whether a location at which degree of divergence in voltage values among the phases exceeds a predetermined criterion is present; and outputting a result of the determining.

### CROSS-REFERENCE TO RELATED APPLICATION

This application is based upon and claims the benefit of priority of the prior Japanese Patent Application No. 2013-211945, filed on Oct. 9, 2013, the entire contents of which are incorporated herein by reference.

### FIELD

The embodiments discussed herein are related to an imbalance determining method, an imbalance determining apparatus, and recording medium.

### BACKGROUND

In a high-voltage power distribution line of a power distribution system, a three-phase three-wire system is employed, for example. Low-voltage users represented by ordinary homes are supplied from the high-voltage power distribution line with a voltage lowered via a transformer. At this time, the transformer is connected to any two wires out of the three wires of the high-voltage power distribution line. This connecting portion is referred to as a connection phase.

Consequently, in the high-voltage power distribution line, depending on the connection situation and load situation of a transformer, there may be a situation in which the imbalance of voltages occurs among the respective phases of the three-phase three-line system. This may cause the fluctuation range of the voltage to be large, and may also cause a bias in utilization rate. This is referred to as three-phase imbalance.

A variety of measures have been available to identify this three-phase imbalance.

For example, Japanese Laid-open Patent Publication No. 2011-101565 (Patent Document 1) describes that, by the difference in voltage imbalance rates between two switches and by the amount of power consumption of respective users located between the two switches measured by voltage measuring instruments provided on the switches in a given period of time, it is possible to understand which of the three-phase power distribution lines the cause of power disequilibrium is occurring in, and it is also possible to determine which user load is the cause of the power disequilibrium.

Furthermore, Japanese Laid-open Patent Publication No. 2011-217465 (Patent Document 2) describes a module that determines, based on the current of each phase measured by respective phase-current measuring instruments that detect the current of the respective phases of the power distribution line on the three-phase side and are attached to section switches, the magnitude of each phase current and the tendency of the change thereof for each given period of time, and detects the imbalance in the current of the respective phases of the power distribution line on the three-phase side.

In the technologies disclosed in Patent Document 1 and Patent Document 2, however, it is not possible to identify a transformer.

### SUMMARY

According to an aspect of the embodiments, a non-transitory computer-readable recording medium has stored therein a program that causes a computer to execute an imbalance determining process. The imbalance determining process includes: analyzing fluctuation situations of voltage values of respective phases in a power distribution line using a three-phase three-wire system; determining whether a location at which degree of divergence in voltage values among the phases exceeds a predetermined criterion is present; and outputting a result of the determining.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating the functional configuration of a determining apparatus;

FIG. 2 is a diagram illustrating one example of facilities constituting a power distribution system;

FIG. 3 is a diagram schematically illustrating one example of the connection relation of the power distribution system represented by power-distribution system information;

FIG. 4 is a diagram schematically illustrating one example of the connection relation of the power distribution system represented by the power-distribution system information;

FIGS. 5A to 5C are diagrams illustrating the connection relation of the power distribution system in a graph structure;

FIGS. 6A to 6C are diagrams illustrating the connection relation of the power distribution system in a graph structure;

FIGS. 7A to 7C are diagrams illustrating one example of a process to identify a time change pattern of a highest correlation;

FIGS. 8A to 8C are diagrams illustrating another example of the process to identify a time change pattern of a highest correlation;

FIG. 9 is a table illustrating one example of the data structure of connection phase information;

FIG. 10 is a wiring diagram schematically illustrating a connection state of banks #1 to #6 to a high-voltage line;

FIG. 11 is a table illustrating one example of the voltages of respective phases of the high-voltage line at a power-distribution substation and the banks #1 to #6;

FIG. 12 is a graph illustrating one example of voltage values of the respective phases in the power distribution system;

FIG. 13 is a diagram illustrating one example of a process of updating a connection phase;

FIG. 14 is a diagram schematically illustrating the connection state of the banks #1 to #6 to the high-voltage line;

FIG. 15 is a table illustrating one example of the voltages of the respective phases of the high-voltage line at the power-distribution substation and the banks #1 to #6;

FIG. 16 is a graph illustrating one example of the voltage values of the respective phases in the power distribution system;

FIG. 17 is a flowchart illustrating a procedure of a determining process; and

FIG. 18 is a block diagram illustrating an example of a computer that executes a determining program.

### DESCRIPTION OF EMBODIMENTS

Preferred embodiments will be explained with reference to accompanying drawings. The embodiments, however, are not intended to limit the disclosing technology. Each of the embodiments can be combined appropriately within a range not making the content of process inconsistent.

### [a] First Embodiment

### Configuration of Determining Apparatus

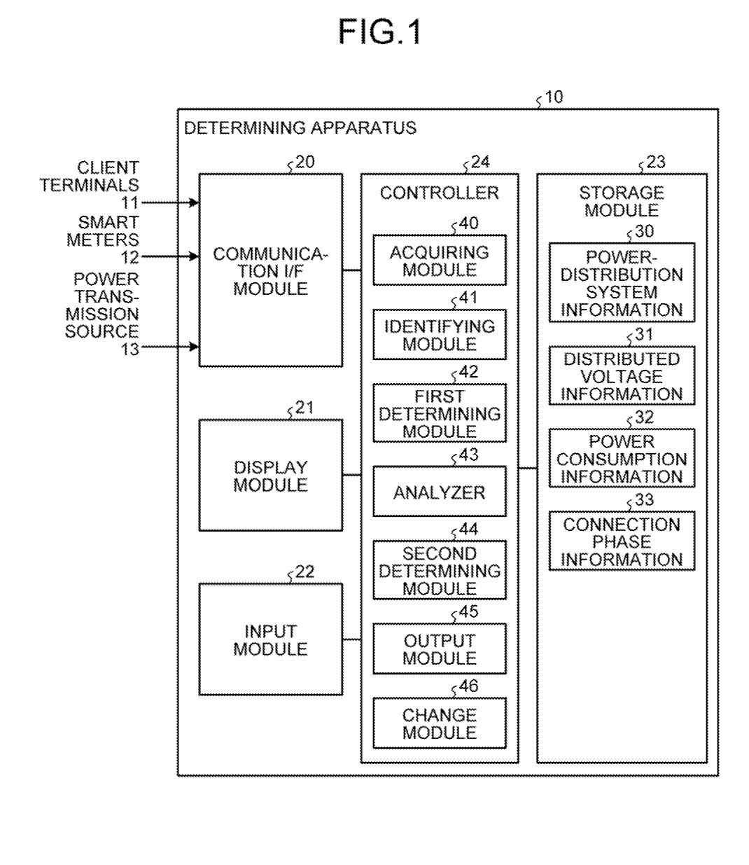

FIG. 1 is a block diagram illustrating the functional configuration of a determining apparatus. A determining apparatus 10 illustrated in FIG. 1 is a device that performs a determining process in which the voltage of a power distribution system for each phase is calculated and the occurrence of imbalance is determined.

The determining apparatus 10, as one aspect thereof, may be implemented as a web server that executes the above-described process. Alternatively, the determining apparatus 10 can be implemented as a cloud computing that provides a service concerning the above-described process by outsourcing. As another aspect, the determining apparatus 10 can be implemented on a desired computer by being pre-installed with or by installing a determining program that is provided as packaged software or on-line software.

As illustrated in FIG. 1, the determining apparatus 10 is connected, via a given network, to be able to perform communication with other devices such as client terminals 11, smart meters 12, and a device provided in a power transmission source 13. For such a network, any type of communication network such as the Internet, a local area network (LAN), and a virtual private network (VPN) can be employed regardless of being wired or wireless. Note that any number of the client terminals 11 and any number of the smart meters 12 can be connected.

The client terminal 11 out of the foregoing is a terminal device to operate the determining apparatus 10 from the outside. As one example of such a client terminal 11, other than a fixed terminal including a personal computer (PC), a mobile terminal such as a cellular phone, a personal handyphone system (PHS), and a personal digital assistant (PDA) can be employed. The client terminal 11 is used by a member of an electric power supplier, for example, a staff member or an administrator of a power distribution sector.

The smart meter 12 is an electrical-power measuring instrument equipped with a communication function. Such a smart meter 12 is connected to a distribution board of a user or the like. As one aspect, the smart meter 12 measures electrical power used by a load system of the user for a given period of time, for example, for each 30 minutes. At this time, the smart meter 12 measures the electrical power used by the load system in a cumulative manner. In the following description, the value of the electrical power consumed by the load system measured cumulatively may be described as “power consumption”. The smart meter 12 then transmits the power consumption and the date and time of measurement to the determining apparatus 10. The date and time of measurement is defined as the date and time at which the time period to measure the power consumption ended, for example. While the smart meter is exemplified here to upload the power consumption for each given period of time, the power consumption can be uploaded intermittently. Furthermore, the smart meter 12 can upload the power consumption, not actively, but in response to a request from the determining apparatus 10.

The power transmission source 13 is an electric power facility that distributes electrical power to the power distribution system. The power transmission source 13 includes an electric power plant, a transformer substation, a given location of a high-voltage power distribution line, and others. In the first embodiment, the power transmission source 13 corresponds to a high-voltage power distribution line drawn out from a later-described power-distribution substation. The device provided on the power transmission source 13 periodically transmits the information of the voltages distributed to the power distribution system and the date and time the voltages were measured to the determining apparatus 10. For example, the device provided on the power transmission source 13 periodically transmits, to the determining apparatus 10, respective voltage values distributed to the three wires of the power distribution system in three-phase three-wire system together with the date and time of measurement. The device provided on the power transmission source 13 may transmit, for each given period of time, the information of the voltages distributed to the power distribution system at a plurality of the time within the given period of time. Furthermore, the device provided on the power transmission source 13 may transmit the voltages distributed to the power distribution system and the date and time the voltages were measured to the determining apparatus 10 in every 30 minutes at which the smart meter 12 uploads the power consumption, for example.

The determining apparatus 10 includes a communication interface (I/F) module 20, a display module 21, an input module 22, a storage module 23, and a controller 24. The determining apparatus 10 may include, other than the functional modules illustrated in FIG. 1, various functional modules that a known computer has.

The communication I/F module 20 is an interface that controls communication with other devices, for example, the client terminals 11, the smart meters 12, and the device provided on the power transmission source 13. As one aspect of the communication I/F module 20, a network interface card such as a LAN card can be employed. For example, the communication I/F module 20 receives various information, for example, various instruction information from the client terminal 11, or posts image data of various screens from the determining apparatus 10 to the client terminal 11.

The display module 21 is a display device that displays various information. As for the display module 21, a display device such as a liquid crystal display (LCD) and a cathode ray tube (CRT) can be included. The display module 21 displays various information. For example, the display module 21 displays various screens including an investigation-target specifying screen and a degradation location screen which will be described later.

The input module 22 is an input device to which various information is entered. The input module 22, for example, includes an input device such as a mouse and a keyboard. The input module 22 receives operating input from an administrator and others who manage the system, and enters operating information indicative of the operating content received to the controller 24.

The storage module 23 is a storage device that stores therein various programs executed by the controller 24 such as an operating system (OS) and a program that performs a later-described determining process. The storage module 23 includes, as one aspect, a semiconductor memory such as a flash memory, and a storage device such as a hard disk and an optical disk. The storage module 23 is not limited to the above-described types of storage devices, and may be a random access memory (RAM) and a read only memory (ROM).

The storage module 23 stores therein power-distribution system information 30, distributed voltage information 31, power consumption information 32, and connection phase information 33, as one example of data used for the program executed by the controller 24. Other than the information exemplified in the foregoing, the storage module 23 can additionally store therein other electronic data.

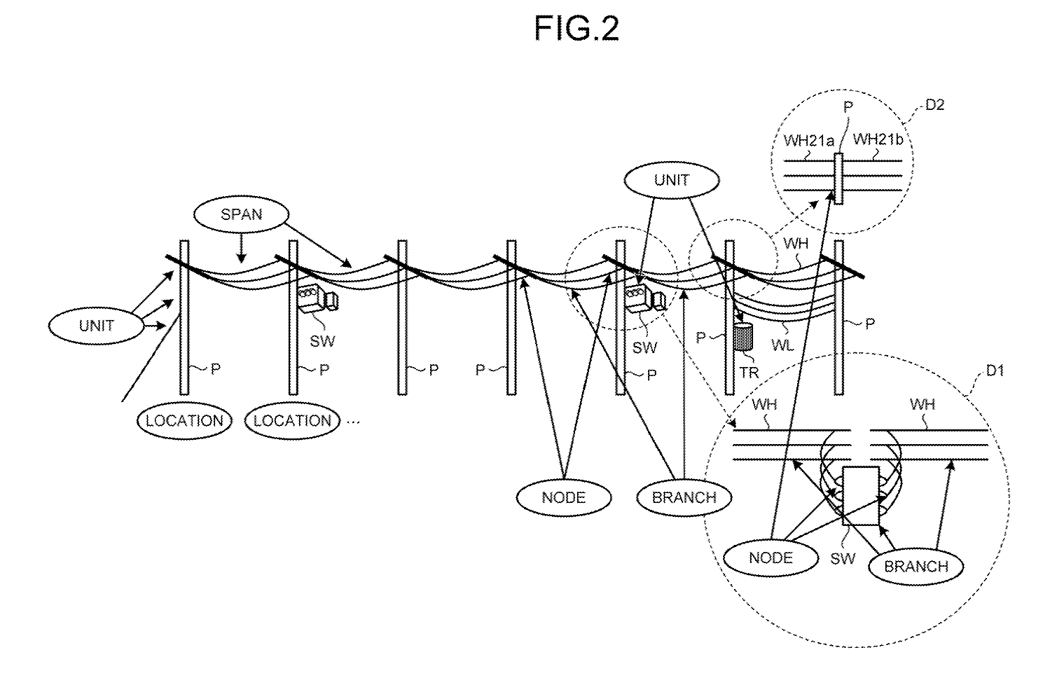

The facilities that constitute a power distribution system include a facility of “unit” that is linked to one location and a facility of “span” that is linked to two locations. FIG. 2 is a diagram illustrating one example of the facilities constituting a power distribution system. One example of the unit includes a power pole P, a switch SW, and a pole transformer TR. Other than those, the category of the unit further includes a power-distribution substation, a step voltage regulator (SVR), and various meter gauges such as the smart meter 12, although not depicted. In addition, the category of the unit includes a manhole, which is an underground facility, and a hand hole.

One example of the span includes an electrical wire that is laid in a high-voltage system to distribute high-voltage power between a power distribution substation and a pole transformer TR, and is what is called “high-voltage line”. Another example of the span includes an electrical wire that is laid in a section between a pole transformer TR and a service line in a low-voltage system to distribute low-voltage power between the pole transformer TR and the load system of the user, and that is what is called “low-voltage line”. Yet another example of the span includes an electrical wire that is laid in a section between a service line and a load system, and that is what is called “service line”. One example of the span further includes a cable buried underground. Note that, for an electrical wire W such as the high-voltage line WH and the low-voltage line WL, the number of wires in a unit laid to a power pole P, for example, three wires and two wires, can be handled collectively as the span.

Referring back to FIG. 1, the power-distribution system information 30 is the data storing therein the information concerning various facilities such as units and spans constituting a power distribution system. For example, the power-distribution system information 30 stores therein the information concerning the connection relations, locations, types, specifications, and attributes of the various facilities constituting the power distribution system. The power-distribution system information 30 may include a plurality of tables. For example, the power-distribution system information 30 may separately include a table storing therein the connection relations of facilities, a table storing therein the locations of the facilities, and a table storing therein the types, specifications, and attributes of the facilities.

The attributes stored in the power-distribution system information 30 include, in case of a span, the model number, thickness, material, span length, resistance value per unit (m), and reactance value per unit (m) of the span, for example. Furthermore, the attributes include, in case of a unit, the model number and performance of the unit, and when the unit is a transformer, for example, the attributes include electrical characteristics such as the capacity and voltage ratio of the transformer. Such attribute information is used for the calculation of voltages in the power distribution system, for example.

Furthermore, the power-distribution system information 30 stores therein positional information being associated with the various facilities constituting the power distribution system, for example. The power-distribution system information 30 stores therein, in case of a unit, a single piece of positional information being associated with the unit, and in case of a span, two pieces of positional information being associated with the span, for example.

In the first embodiment, the connection relation of the facilities constituting the power distribution system is managed by a connection point of “node” at which facilities are electrically connected with each other, and by a facility of “branch” that is defined by a plurality of connection points.

One example of the node includes a connection point of the high-voltage line WH and the switch SW illustrated in an enlarged view D1 in FIG. 2, a connection point of the high-voltage line WH and the pole transformer TR, and a connection point of the pole transformer TR and the low-voltage line WL. Other than those, the connection point of a high-voltage line WH21a and a high-voltage line WH21b illustrated in an enlarged view D2 in FIG. 2 is also included in the category of the node. More specifically, even when the high-voltage line WH21a and the high-voltage line WH21b are wired to the power pole P of a through pole, the high-voltage line WH21a and the high-voltage line WH21b are regarded as being electrically connected therebetween, and thus the connection point of the high-voltage lines WH is handled as a virtual node.

One example of the branch includes various facilities such as the power pole P, the high-voltage line WH, the switch SW, the pole transformer TR, and the low-voltage line WL illustrated in FIG. 2. Other than those, a power-distribution substation, a service line, the smart meter 12, a load system, and others not illustrated are also included in the category of the branch. The facilities located at the end point such as a power-distribution substation and a load system may only have one node.

Referring back to FIG. 1, the power-distribution system information 30 stores therein identification information of the nodes and branches of various facilities, being associated with the respective facilities constituting the power distribution system. Tracing the identification information of the nodes and branches can obtain the connection relation of the various facilities constituting the power distribution system.

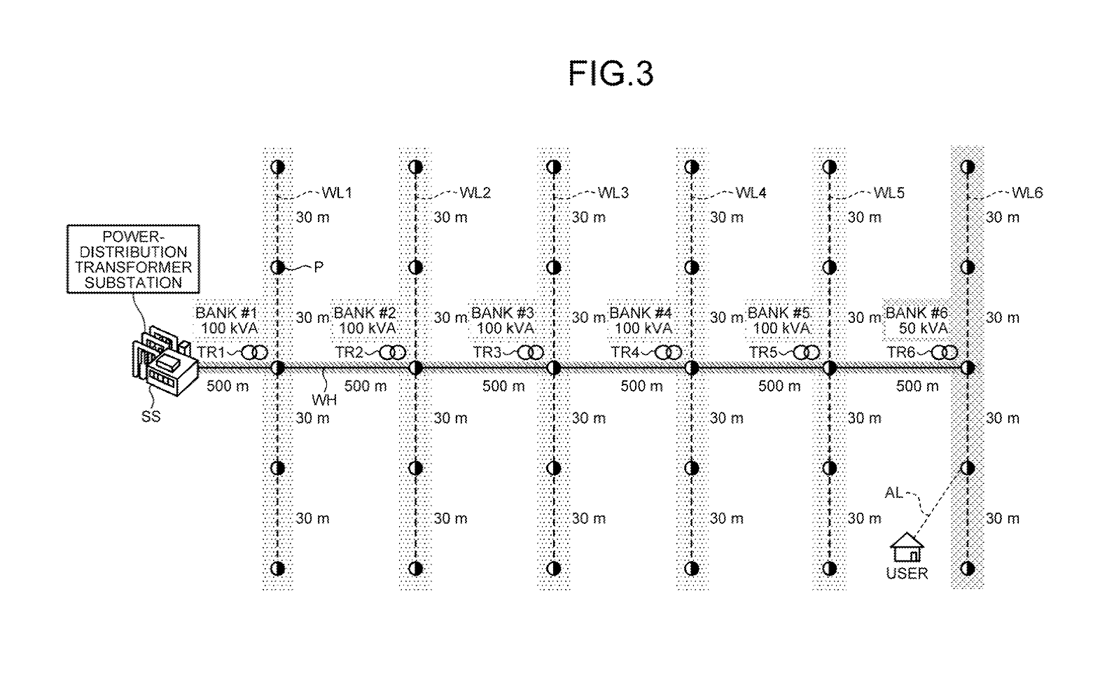

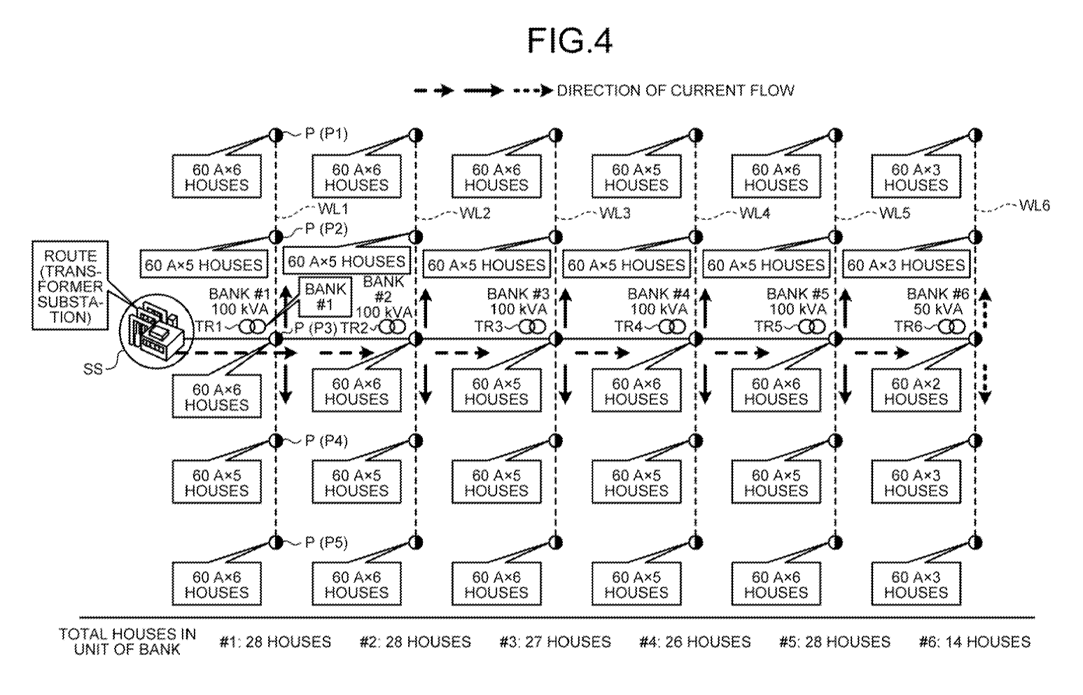

FIGS. 3 and 4 are diagrams schematically illustrating one example of the connection relation of a power distribution system represented by the power-distribution system information. In the example in FIG. 3, schematically illustrated is the connection relation of a power-distribution substation SS, the high-voltage line WH, and six low-voltage lines WL1 to WL6. The high-voltage line WH is connected to the power-distribution substation SS, and high-voltage power is distributed by three electrical wires in three-phase three-wire system. The high-voltage line WH is wired to the power pole P, and is connected to the low-voltage lines WL1 to WL6 via pole transformers TR1 to TR6. In the following description, the pole transformers TR1 to TR6 may also be expressed as banks #1 to #6, respectively. The pole transformers TR1 to TR6 are each connected to two electrical wires out of three electrical wires of the high-voltage line WH, and distribute low-voltage power, for which the high-voltage power is lowered to a given voltage, to the low-voltage line WL. The low-voltage line WL is also wired to the power pole P, and at the power pole P, a service line is connected and the electrical power is supplied to the user via the service line. In the example in FIG. 3, the low-voltage line WL6 is connected with a service line AL, and via the service line AL, the electrical power is supplied to the user.

In the example in FIG. 4, schematically illustrated is the connection relation of low-voltage lines and the users. The low-voltage lines WL1 to WL6 are each connected with the users via the service lines AL not depicted. In the example in FIG. 4, at a power pole P1 of the low-voltage line WL1, six houses of the users with a contract amperage of 60 amps are connected, and at a power pole P2 of the low-voltage line WL1, five houses of the users with the contract amperage of 60 amps are connected, for example. Furthermore, at a power pole P3 of the low-voltage line WL1, six houses of the users with the contract amperage of 60 amps are connected, at a power pole P4 of the low-voltage line WL1, five houses of the users with the contract amperage of 60 amps are connected, and at a power pole P5 of the low-voltage line WL1, six houses of the users with the contract amperage of 60 amps are connected. In FIG. 4, the numbers of users connected are indicated in a unit of a transformer (bank).

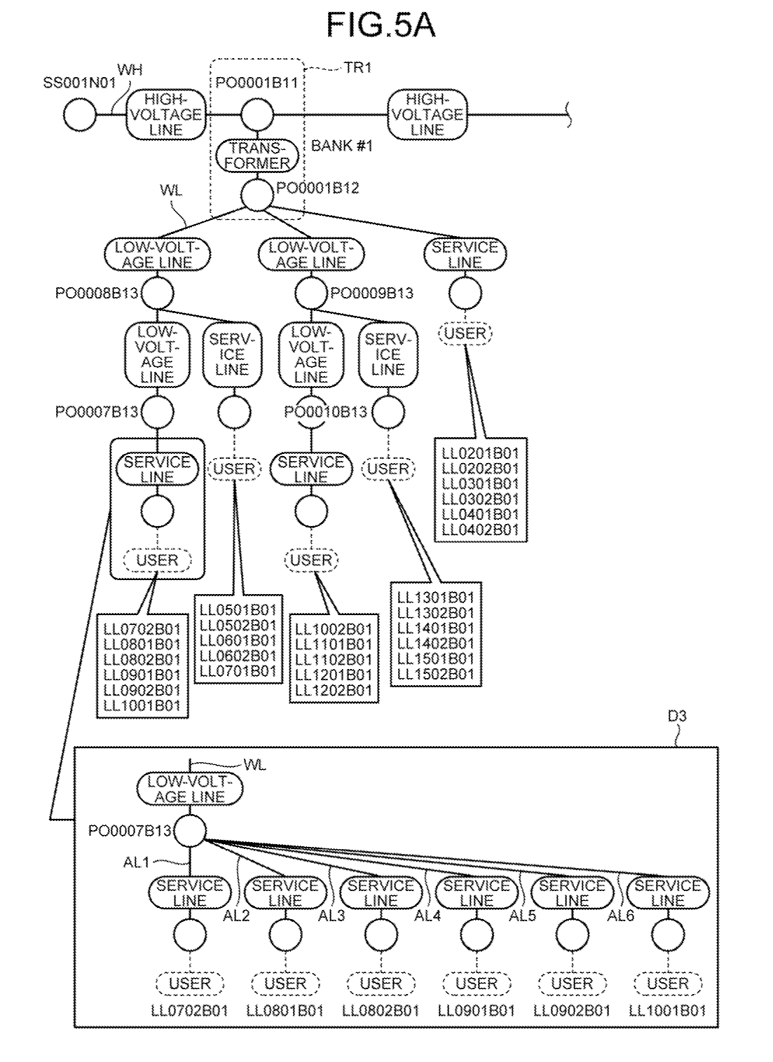

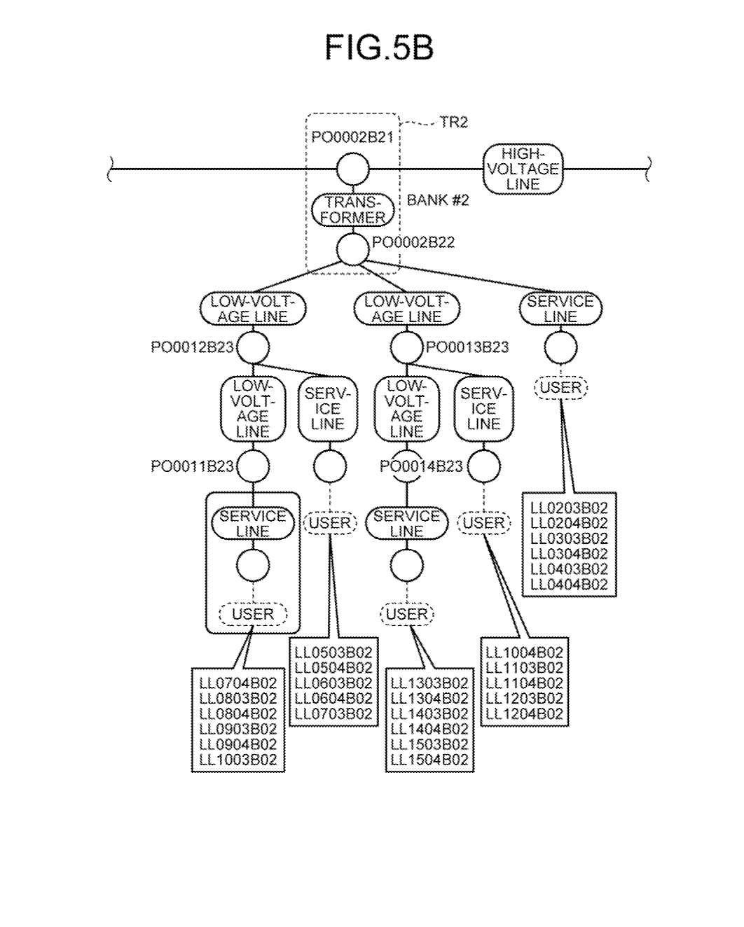

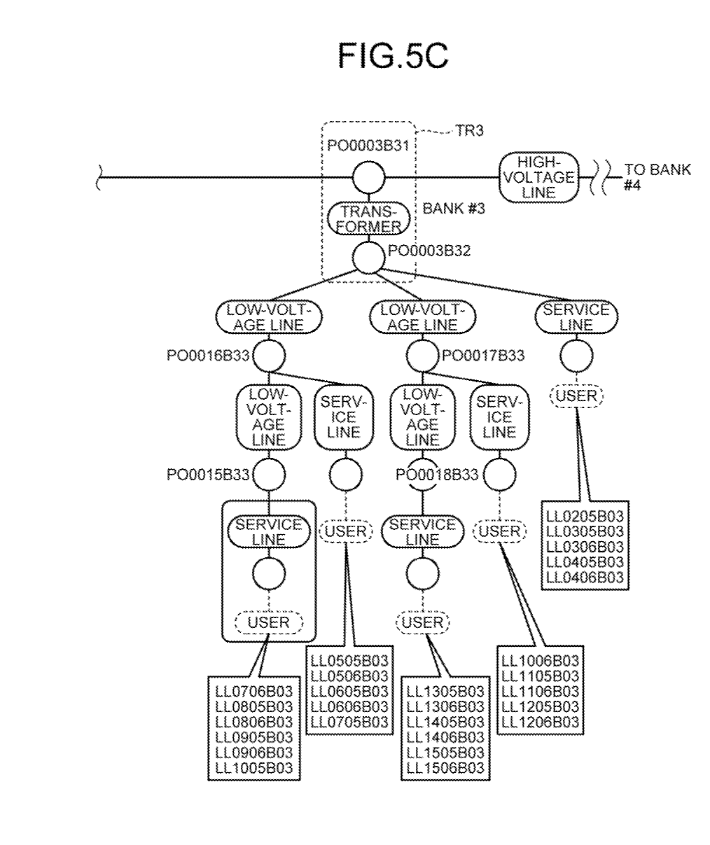

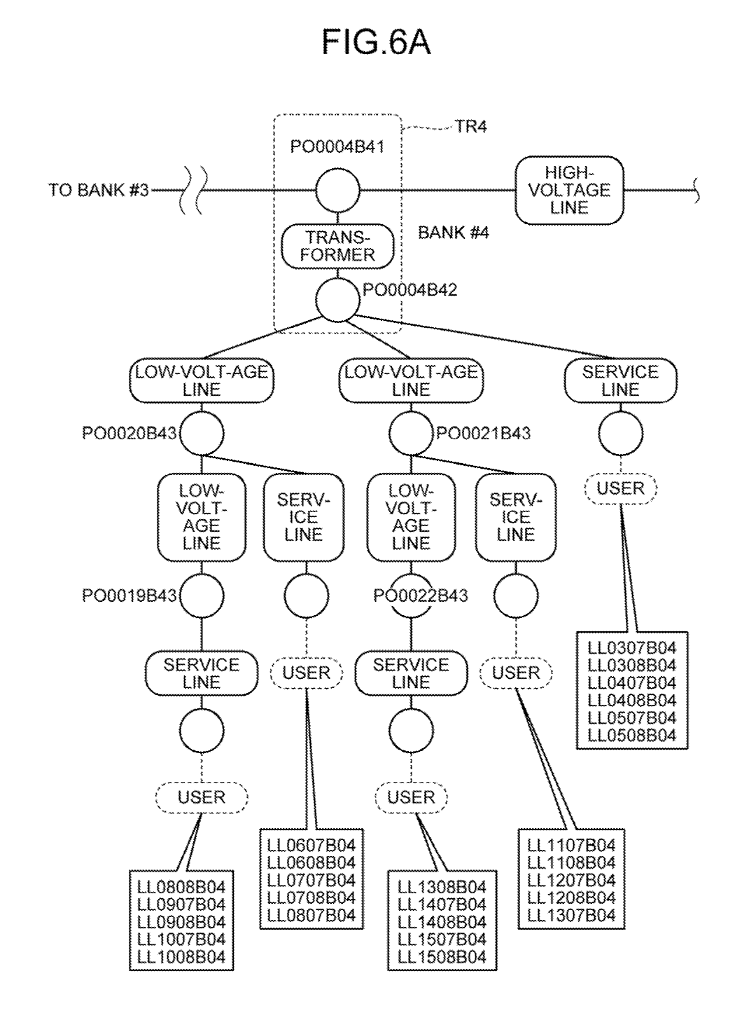

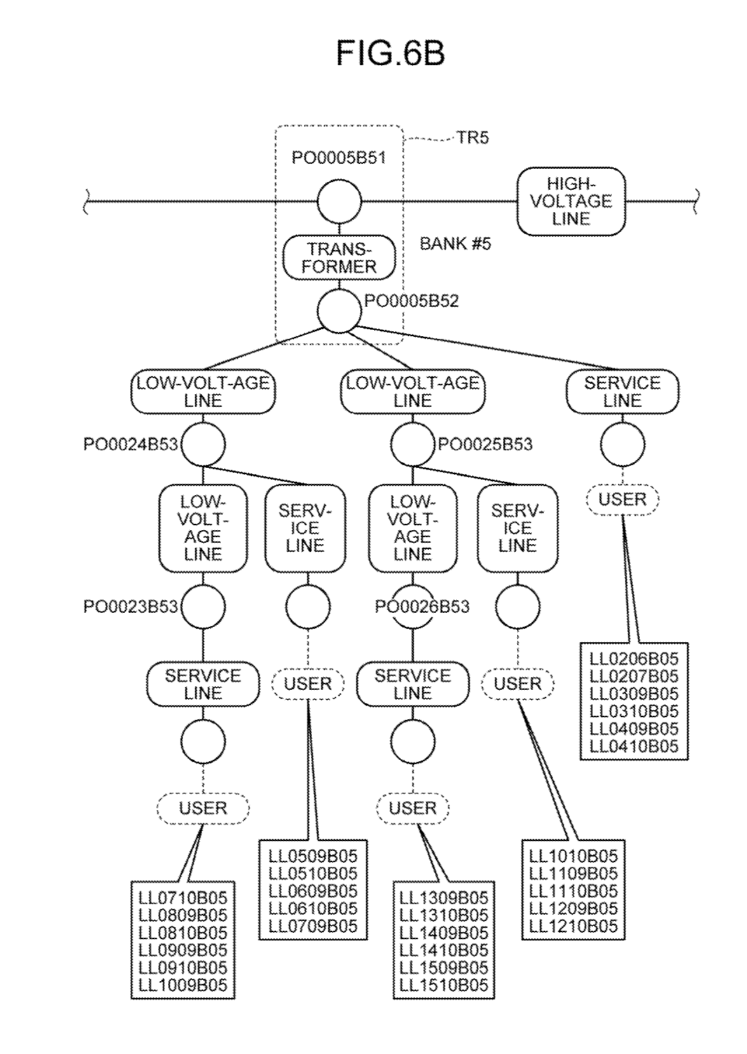

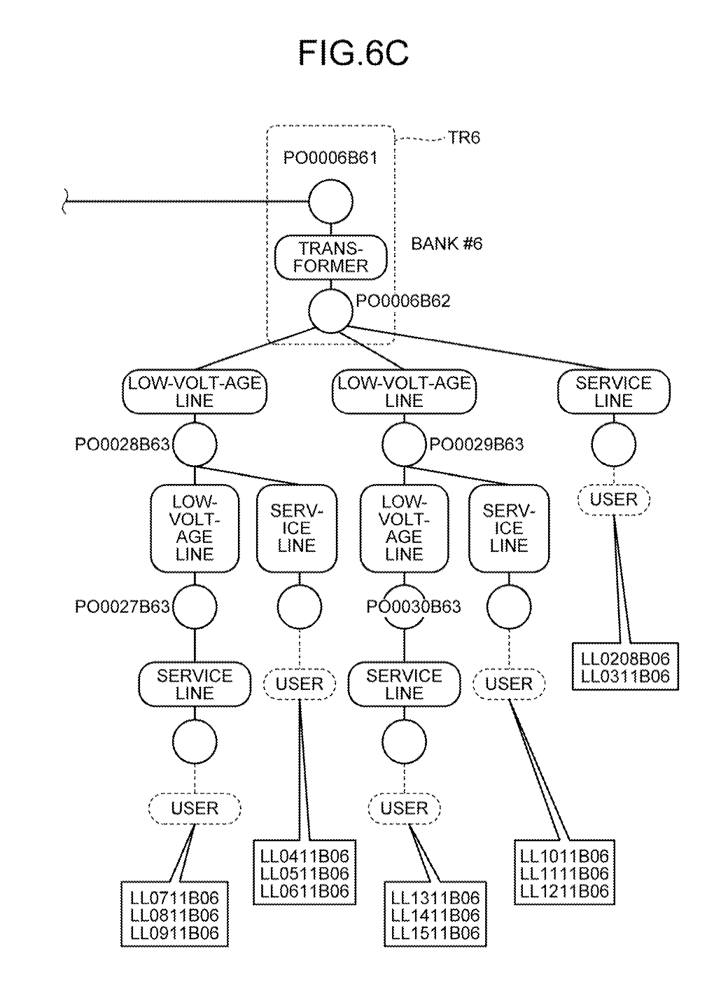

FIGS. 5A to 5C and 6A to 6C are diagrams illustrating the connection relation of the power distribution system in a graph structure. In the examples in FIGS. 5A to 5C and 6A to 6C, illustrated is the connection relation of the power distribution system illustrated in FIGS. 3 and 4 in a graph structure. In the examples in FIGS. 5A to 5C and 6A to 6C, illustrated are the various facilities, and the nodes and branches that are the respective connection points thereof. In the examples in FIGS. 5A to 5C and 6A to 6C, further illustrated are IDs that are the identification information assigned to and associated with the respective nodes and branches. In the examples in FIGS. 5A to 5C and 6A to 6C, the IDs are indicated with the addition of a prefix of a character string that can identify the type of facilities such as “SS” representing a power-distribution substation, “PO” representing a power pole, and “LL” representing a user. For example, the high-voltage line WH is connected with the power-distribution substation at the node of ID “SS001N01”. The high-voltage line WH is further connected to the pole transformers TR1 to TR6 at the respective nodes of IDs “PO0001B11”, “PO0002B21”, “PO0003B31”, “PO0004B41”, “PO00005B51”, and “PO0006B61”. The pole transformers TR1 to TR6 are connected to the users via the respective low-voltage lines WL. For example, the pole transformer TR1 is connected to the low-voltage line WL at the node of ID “PO0001B12”. The low-voltage line WL is, as illustrated in an enlarged view D3 in FIGS. 5A to 5C, connected with service lines AL1 to AL6 at the node of ID “PO0007B13”. The service lines AL1 to AL6 are connected to the users at the respective nodes of IDs “LL0702B01”, “LL0801B01”, “LL0802B01”, “LL0901B01”, “LL0902B01”, and “LL1001B01”.

Referring back to FIG. 1, the distributed voltage information 31 is the data storing therein various information concerning the electrical power distributed to the power distribution system. For example, the distributed voltage information 31 stores therein the information concerning the distributed voltages to the power distribution system and the date and time of measurement thereof, which are uploaded periodically from a device provided on the power-distribution substation SS and a high-voltage power distribution line as the power transmission source 13.

The power consumption information 32 is the data storing therein various information concerning the electrical power received from the smart meter 12 installed to the user. For example, the power consumption information 32 stores therein the information of the power consumption of the user and the information concerning the date and time of measurement thereof, which are periodically posted from the smart meter 12.

The connection phase information 33 out of the information stored in the storage module 23, other than the power-distribution system information 30, the distributed voltage information 31, and the power consumption information 32 described above, will be described later along with the description of functional modules that generate, acquire, or use the foregoing information.

The controller 24 includes an internal memory to store therein programs that define procedures of various processes and control data, and executes the various processes with the foregoing. The controller 24 includes, as illustrated in FIG. 1, an acquiring module 40, an identifying module 41, a first determining module 42, an analyzer 43, a second determining module 44, an output module 45, and a change module 46.

The acquiring module 40 is a processing module that acquires various information. For example, the acquiring module 40 acquires the voltage of the high-voltage power distribution line drawn out from the power-distribution substation SS as the information of the voltage of the power distribution system. As one aspect, the acquiring module 40 acquires the distributed voltages of the three wires of the power distribution system and the date and time of measurement thereof, which are updated from a device provided on the high-voltage power distribution line drawn out from the power-distribution substation SS. The date and time of measurement may be defined as the date and time of the data uploaded. The acquiring module 40 adds and registers the acquired distributed voltages and the date and time of measurement thereof to the distributed voltage information 31.

Furthermore, the acquiring module 40 acquires the power consumption of the smart meter 12 and the date and time of measurement thereof as the load information of a power consuming facility, for example. As one aspect, the acquiring module 40 acquires the power consumption and the date and time of measurement thereof, which are updated from the smart meter 12 connected to the load system of each user. The date and time of measurement may be defined as the date and time of the data uploaded. The acquiring module 40 adds and registers the facility ID of the load system to which the smart meter 12 is connected, and the power consumption and the date and time of measurement thereof to the power consumption information 32. For example, assumed is a situation of the smart meters 12 to update the respective power consumption in a given period of time, for example, every 30 minutes. In the power consumption information 32, stored is the load information of the power consuming facilities acquired for each given period of time. For example, in the power consumption information 32, for each smart meter 12, the data is registered in a period of time corresponding to the sum of a meter reading interval, at which the smart meter 12 is made to post the meter reading result of power consumption, and a transmission delay time between the power consumption information 32 and the determining apparatus 10.

Now, a transformer such as the pole transformer TR is connected to two wires out of the three wires of the high-voltage line WH in a three-phase three-wire system, and distributes the low-voltage power, for which the electrical power of the connected two wires is transformed to a given voltage, to the low-voltage line WL. To the user, the low-voltage power transformed by the transformer is distributed via the low-voltage line WL. Consequently, when a large amount of power is consumed by a particular user, or when the transformers are connected to specific two wires out of the three wires of the high-voltage line WH, a three-phase imbalance occurs among the voltages of the three phases of the high-voltage line WH. Furthermore, the power consumption obtainable from the power consumption information 32, which is uploaded from the smart meter 12 provided on the user, changes the power consumption of the phases of the two wires, which are connected with the low-voltage line WL that distributes the low-voltage power to the user, out of the three wires of the high-voltage line WH in the same pattern.

The identifying module 41 is a processing module that performs various identification. For example, the identifying module 41 identifies, from the distributed voltage information 31, time change patterns of the voltages of the three phases distributed to the three wires of the high-voltage line WH. The identifying module 41 further identifies, from the power consumption information 32, the time changes in the power consumption of the low-voltage line WL at the user.

For example, the identifying module 41 first calculates the power consumption at each node. As one aspect, when the history concerning the power consumption uploaded from the smart meter 12 is updated to the power consumption information 32, the identifying module 41 starts up the process of combining the power consumption at respective nodes from the nodes of the users toward the node of the transformer substation for each power distribution system.

The identifying module 41 further identifies, based on the distributed voltage information 31, the time change patterns of the three phases of the high-voltage line WH drawn out from the power-distribution substation SS.

The identifying module 41 then obtains, for the same period of time, the correlation of the identified time change patterns of the three phases of the high-voltage line WH and the time change pattern of the power consumption of the low-voltage line WL at the users. For example, the identifying module 41 obtains the correlation of the time change patterns of the three phases of the high-voltage line WH and the time change pattern of the power consumption of the low-voltage line WL at the users for one day. The time period to obtain the correlation of the time change patterns is not limited to one day, and when long time information longer than one year is obtainable, the determination can be made by dividing in a time unit of one month, one week, and others. This is because, even when the time change patterns of other phases are in similar patterns temporarily, the time change patterns of the other phases also change in response to the load situations of the connected users, and thus the time change pattern is rarely in a similar pattern for a long period of time.

The identifying module 41 then identifies, out of the identified time change patterns of the three phases of the high-voltage line WH, the time change pattern of the highest correlation with the time change pattern of the power consumption of the low-voltage line WL at the users.

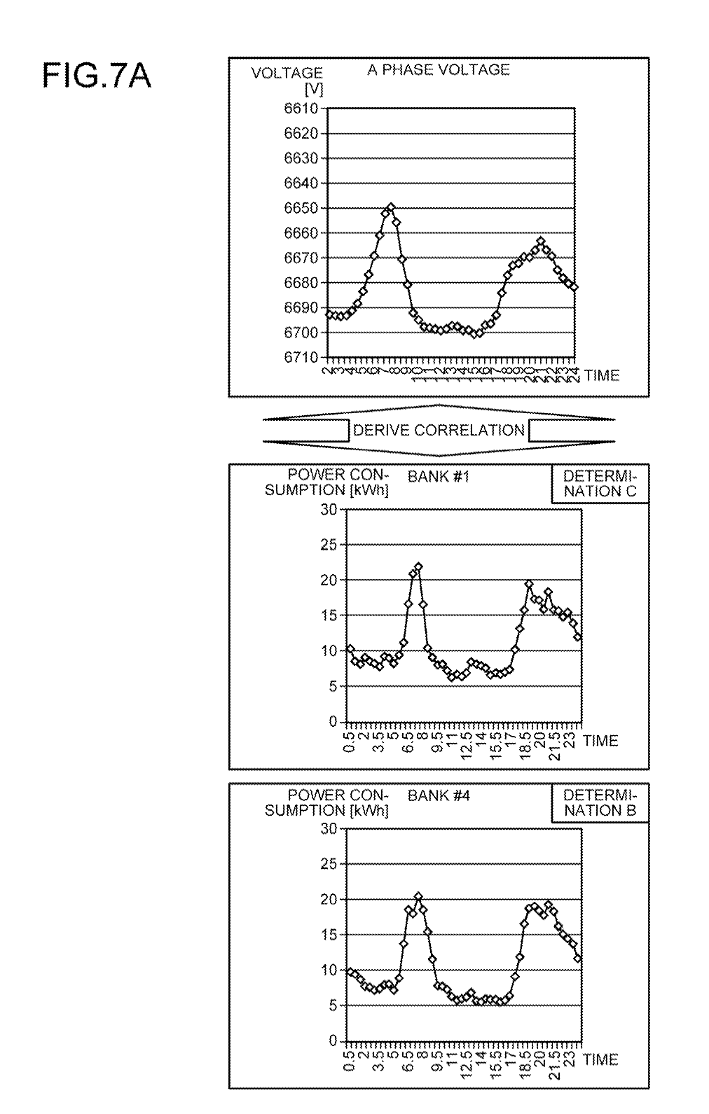

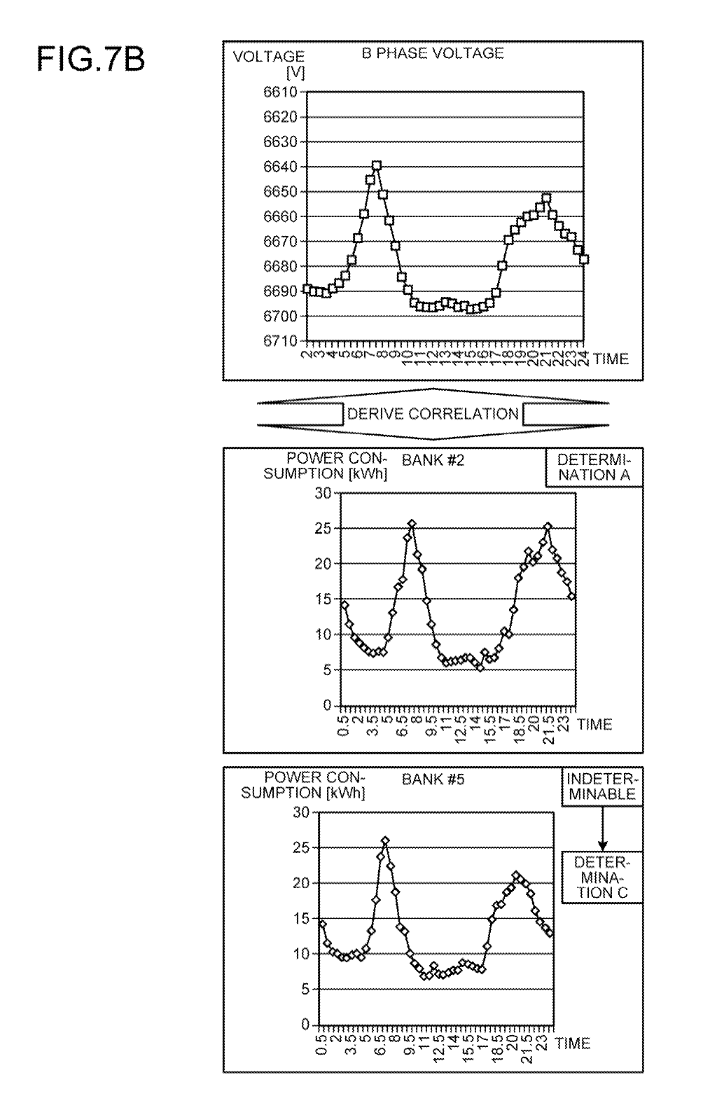

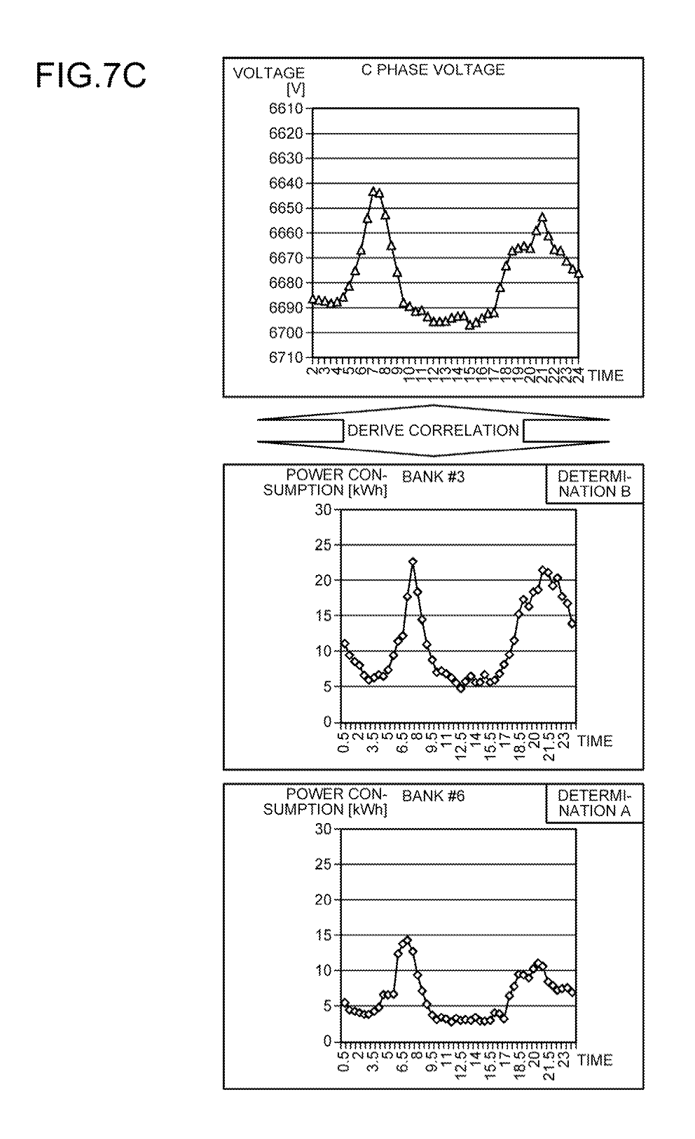

FIGS. 7A to 7C are diagrams illustrating one example of a process to identify the time change pattern of a highest correlation. For example, out of electrical wires 1 to 3 of three wires of the high-voltage line WH, by defining the voltage between the electrical wire 1 and the electrical wire 2 as A phase, the voltage between the electrical wire 2 and the electrical wire 3 as B phase, and the voltage between the electrical wire 3 and the electrical wire 1 as C phase, the identifying module 41 identifies the time change patterns of the voltages of the A phase, the B phase, and the C phase from the power consumption information 32. In the example in FIGS. 7A to 7C, illustrated is one example of the time change patterns of the voltages of the A phase, the B phase, and the C phase.

The identifying module 41 further identifies the time change pattern of the power consumption of the low-voltage line WL at the user from the power consumption information 32. Now, when the information of the smart meters 12 from a plurality of users connected to the same low-voltage line WL is obtainable, the identifying module 41 obtains the power consumption of the low-voltage line WL at the respective users connected to the same low-voltage line WL from the power consumption information 32. The identifying module 41 then combines the power consumption of the low-voltage line WL at the respective users, and measures the time change pattern of the combined value. The time change pattern of the power consumption of the low-voltage line WL corresponds to the time change pattern of the power consumption of a transformer (bank) connected with the low-voltage line WL, and in the example in FIGS. 7A to 7C, one example of the time change patterns at the banks #1 to #6 is illustrated.

The identifying module 41 identifies, for the same period of time, the time change pattern of a highest correlation with the time change pattern of the power consumption of the low-voltage line WL at the users out of the identified time change patterns of the A phase, the B phase, and the C phase of the high-voltage line WH.

The first determining module 42 is a processing module that performs various determinations. For example, the first determining module 42 determines the phase that corresponds to the time change pattern of the highest correlation as the connection phase at the time the transformer is connected to the high-voltage line WH to branch to the low-voltage line WL. In the example in FIGS. 7A to 7C, illustrated is one example of the determined results of the connection phases of the banks #1 to #6. For example, for the bank #1, the connection phase is determined to be the C phase. The first determining module 42 may determine the connection phase to be indeterminable when a correlation value is lower than a given acceptable value to be deemed to be the connection phase. In this case, the determination may be made on the time change pattern in another period of time. In the example in FIGS. 7A to 7C, for the bank #5, the connection phase was once determined to be indeterminable but it has been determined to be the C phase from the time change pattern in the other period of time. As in the foregoing, the determining apparatus 10 can identify the connection phase of the transformer.

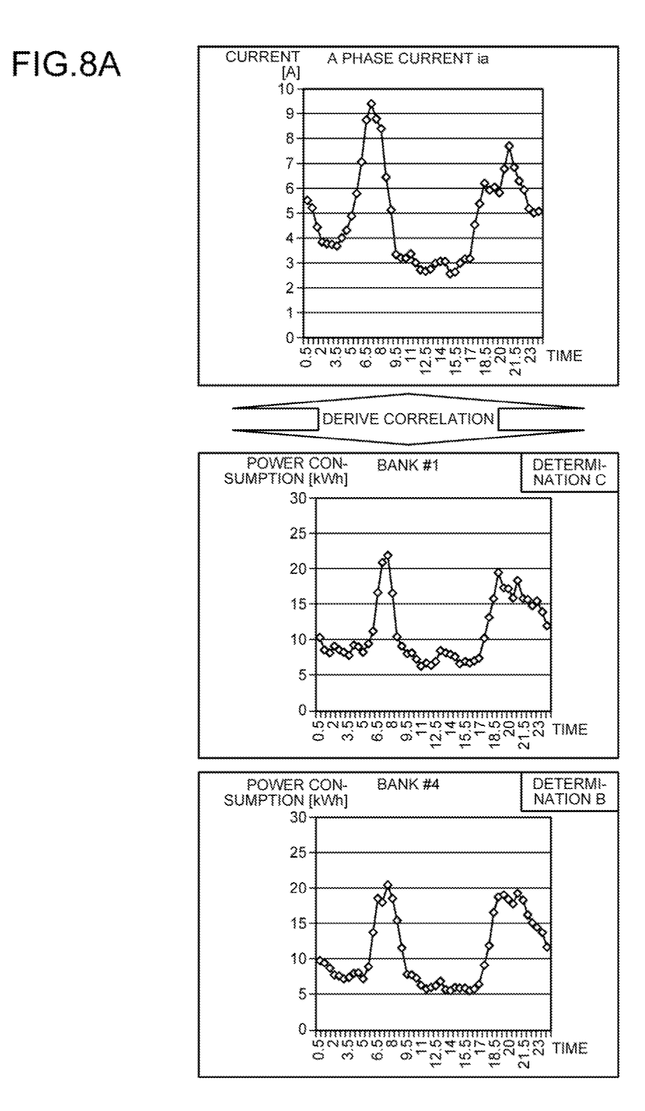

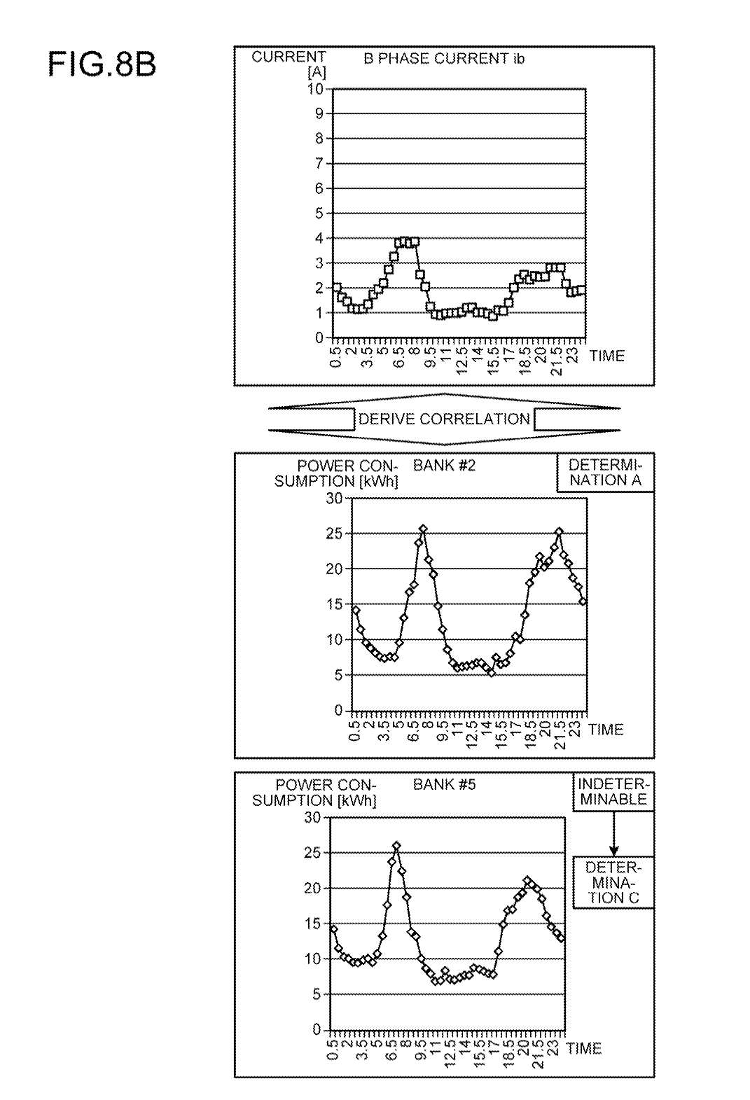

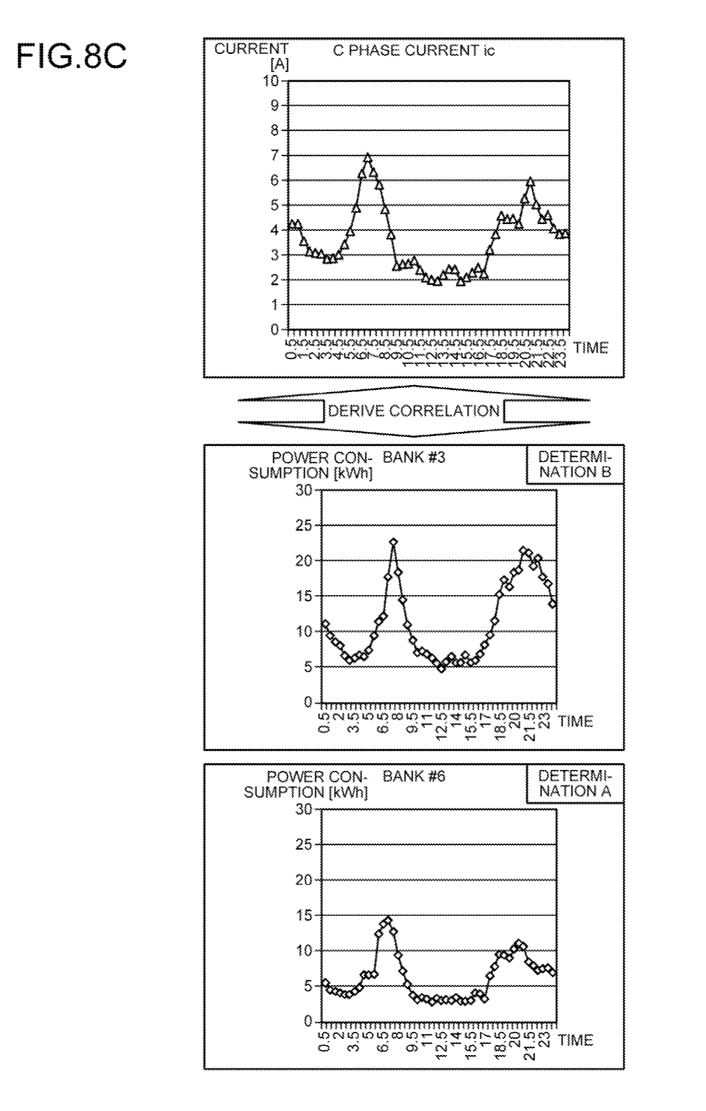

While the situation of determining the connection phase from the time change pattern of the power consumption is exemplified in the first embodiment, the connection phase may be determined from the time change pattern of the voltage or current. For example, the identifying module 41 can calculate an average value of the current flowed during the measurement period by dividing the power consumption of each of the users stored in the power consumption information 32 by the standard voltage of the service line of the respective users and by the measurement period of the power consumption. In this case, when the power consumption or the current of a plurality of users connected to the same power distribution line branched is obtainable, the identifying module 41 may combine the power consumption or the current and measure the time change pattern from the combined value. Furthermore, the connection phase may be determined from the correlation of the time change patterns of the voltages of the banks #1 to #6 with the time change patterns of the current of the A phase, the B phase, and the C phase of the high-voltage line WH, for example. In this case, because the current and the voltage change inversely, either one of the time change patterns is used being turned upside down. FIGS. 8A to 8C are diagrams illustrating another example of the process to identify the time change pattern of a highest correlation. In the example in FIGS. 8A to 8C, out of the time change patterns of the A phase, the B phase, and the C phase of the high-voltage line WH, the phase of the time change pattern of the highest correlation with the time change patterns of the current of the banks #1 to #6 is determined as the connection phase.

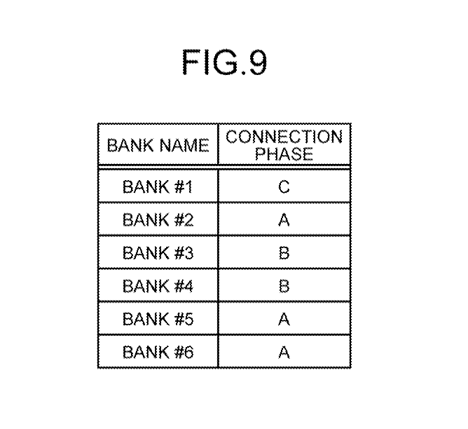

The first determining module 42 stores the determination result in the connection phase information 33. FIG. 9 is a table illustrating one example of the data structure of the connection phase information. In FIG. 9, the banks #1 to #6 and the respective connection phases are stored being associated with each other. Consequently, identifying the connection phase of the transformer can obtain the voltage and current of each node in the power distribution system further accurately.

While the situation of registering the connection phase of the transformer to the connection phase information 33 by identifying the connection phase of the transformer from the correlation of the time change patterns is exemplified in the first embodiment, the connection phase of the transformer may be registered in the connection phase information 33 by other methods. For example, the administrator who manages the power distribution system may register the connection phase of the transformer from the client terminal 11 by visually checking the connection phase of the transformer.

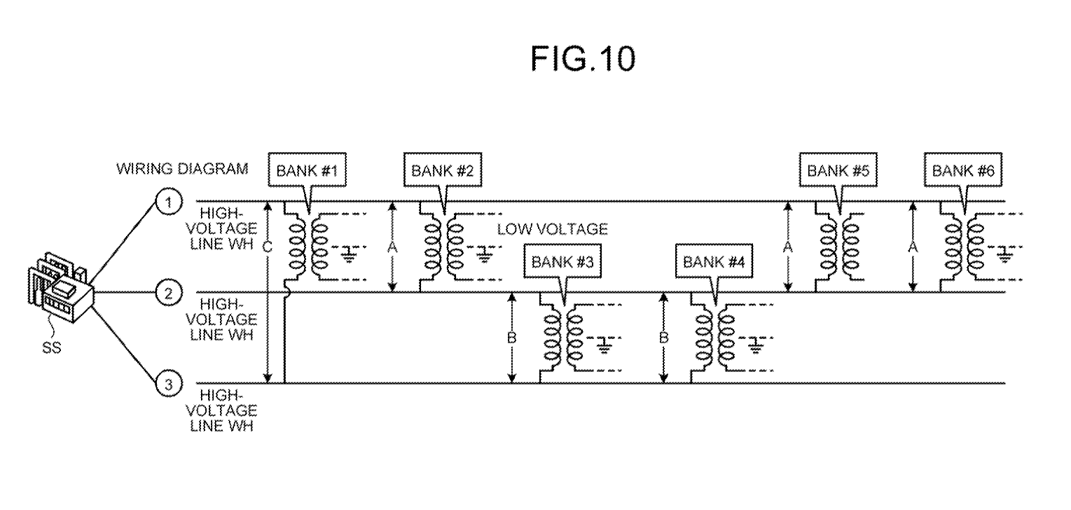

FIG. 10 is a wiring diagram schematically illustrating the connection state of the banks #1 to #6 to the high-voltage line. The bank #1 is connected to the C phase between the electrical wire 1 and the electrical wire 3 out of the electrical wires 1 to 3 of the high-voltage line WH connected to the power-distribution substation SS. The banks #2, #5, and #6 are connected to the A phase between the electrical wire 1 and the electrical wire 2. The banks #3 and #4 are connected to the B phase between the electrical wire 2 and the electrical wire 3.

The analyzer 43 is a processing module that performs various analyses. For example, the analyzer 43 is a processing module that analyzes the situation of fluctuation in the voltage value of each phase in the power distribution system by taking into consideration the information of the connection phase of the transformer stored in the connection phase information 33. The analyzer 43 reads out the information used for the calculation of the voltage from the storage module 23. For example, the analyzer 43 reads out, from the distributed voltage information 31, the voltage of the transmission power transmitted from the transformer substation to the three wires of the power distribution system. Furthermore, the analyzer 43 acquires, from the power-distribution system information 30, the voltage ratio of the transformer, and the resistance, reactance, and others of the electrical wires in addition. The identifying module 43 further reads out the power consumption of the load systems of the respective users from the power consumption information 32.

The analyzer 43 then calculates, assuming that the transformers are connected to the connection phases indicated in the connection phase information 33, the voltage for each phase at each node of the power distribution system by using the read-out parameters. As one example of method of calculating such a voltage, a known algorithm including BFS and Newton-Raphson method can be adaptively employed. The analyzer 43 may calculate the voltage for each phase only at a specific node. For example, the analyzer 43 may calculate the voltage for each phase at the nodes at which the high-voltage line WH of the power distribution system is connected to the banks #1 to #6.

The analyzer 43 further calculates the distance to each node by summing the span lengths of the facilities of the span in the power distribution system. For example, the analyzer 43 calculates the distances from the power-distribution substation SS to the banks #1 to #6.

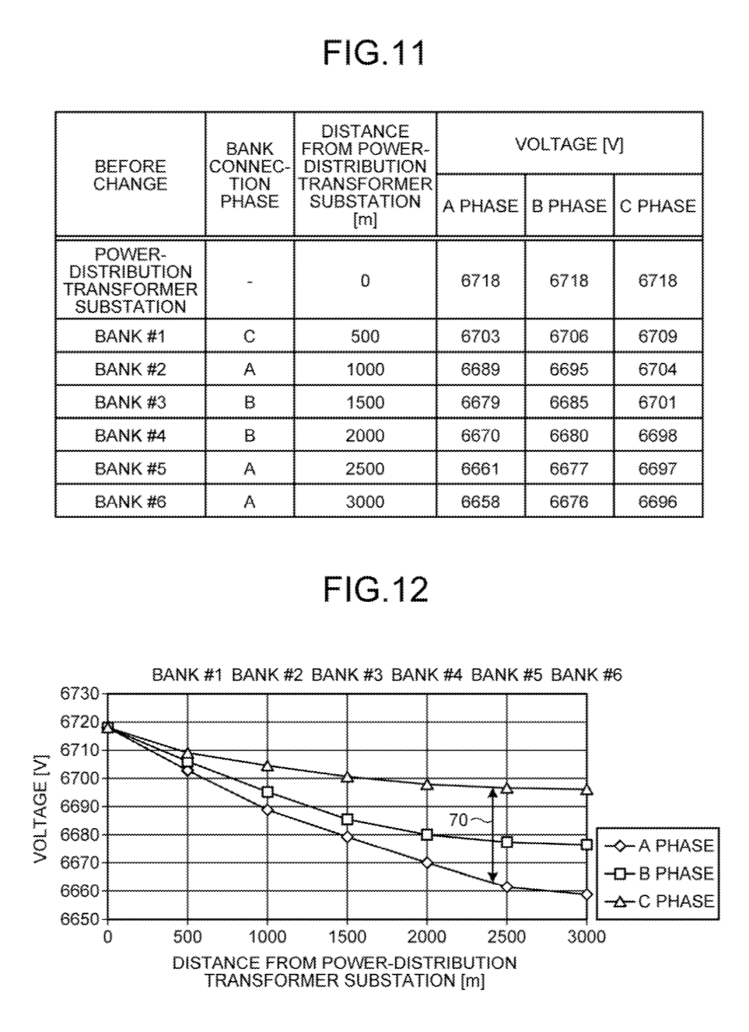

FIG. 11 is a table illustrating one example of voltages of the respective phases of the high-voltage line at the power-distribution substation and the banks #1 to #6. In the example in FIG. 11, illustrated are the calculated results of the voltage of each phase at the power-distribution substation SS and the banks #1 to #6. Furthermore, in the example in FIG. 11, the connection phases of the banks #1 to #6 are indicated. In the example in FIG. 11, the distances from the power-distribution substation SS to the banks #1 to #6 are further indicated.

The second determining module 44 is a processing module that performs various determinations. For example, the second determining module 44 determines, from the voltage value of each phase at each node in the power distribution system calculated by the analyzer 43, whether any location at which the degree of divergence in the voltage values among phases exceeds a given criterion is present for each node. The second determining module 44 calculates the difference in voltage values of the respective phases as the degree of divergence among the phases, and determines whether any location at which the difference in voltage values exceeds a given criterion is present, for example. The difference in voltage values may be obtained for all phases. Alternatively, the difference in voltage values may be obtained only between the phase of the maximum voltage value and the phase of the minimum voltage value. The given criterion is defined based on an imbalance ratio acceptable, for example. For example, when the power distribution system is a system of 6600 volts and if the acceptable imbalance ratio is 1%, the criterion is defined as 66 volts. Furthermore, the second determining module 44 may determine only at a given location, for example, the node at which the high-voltage line and a transformer are connected.

The output module 45 is a processing module that performs various outputs. For example, the output module 45, in response to a request from the client terminal 11, generates image information of a screen including the determination result by the second determining module 44, and outputs the information to the client terminal 11 to display the screen on the client terminal 11. The output module 45 generates and outputs to the client terminal 11 the image information of a screen that displays the voltage values of the respective phases of the power distribution system in the order of distance as a graph, and indicates the location at which the difference in voltage values among the respective phases exceeds the given criterion, for example.

FIG. 12 is a graph illustrating one example of the voltage values of the respective phases in the power distribution system. In the example in FIG. 12, illustrated is a graph indicating the situations of voltage fluctuation by arranging the voltage values of the transformers for the banks #1 to #6 in the order of distance from the power-distribution substation SS, and an arrow 70 indicates the location at which the criterion is first exceeded. When the location at which the criterion is first exceeded is between two neighboring transformers, the output module 45 may identify and display either one of the two transformers as the transformer corresponding to the location. For example, when exceeding the criterion is not permitted at any of the power distribution system, the output module 45 identifies and displays the transformer on the upstream side of the power distribution from the location at which the criterion is first exceeded as the transformer corresponding to the location. In the situation in FIG. 12, the output module 45 may display the bank #4 as the target of connection phase change, for example. Furthermore, when exceeding the criterion is not permitted at transformers but is permitted between the transformers, the output module 45 identifies and displays the transformer on the downstream side of the power distribution from the location at which the criterion is first exceeded as the transformer corresponding to the location. In the situation in FIG. 12, the output module 45 may display the bank #5 as the target of connection phase change, for example. Consequently, referring to the graph enables the staff member of the power distribution sector to identify the occurrence of imbalance. For example, the staff member of the power distribution sector can understand that, from FIG. 12, the difference in voltage values of the respective phases exceeds the criterion subsequent to the bank #5. The staff member of the power distribution sector can further recognize the transformer to be the target of connection phase change.

The change module 46 is a processing module that receives various changes. For example, the change module 46 receives an instruction of connection phase change from the client terminal 11. The staff member of the power distribution sector gives instructions to change the connection phase of a bank from the client terminal 11 to correct the imbalance. For example, in the example in FIG. 12, the staff member of the power distribution sector gives instructions to change the connection phase of the bank #5 from the A phase to the C phase from the client terminal 11. The change module 46 reads out the connection phases of the transformers indicated in the connection phase information 33, and out of the connection phases of the transformers indicated by the read-out data, updates the connection phase to which the change was instructed.

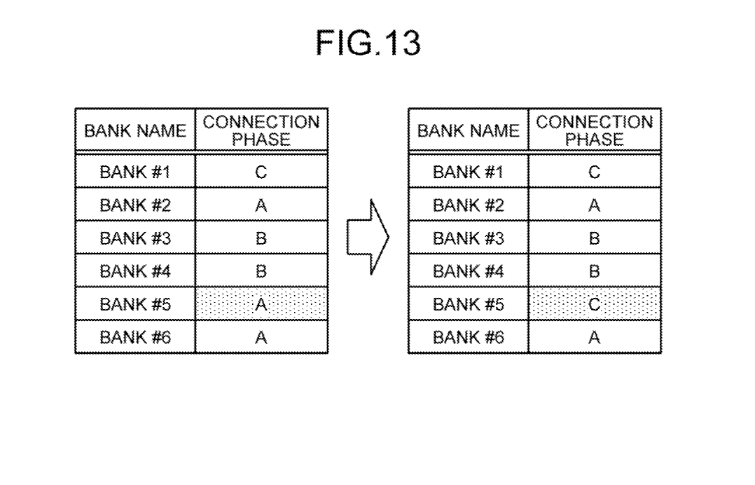

FIG. 13 is a diagram illustrating one example of a process of updating the connection phase. For example, when a change in the connection phase of the bank #5 from the A phase to the C phase was instructed, the change module 46 updates the connection phase of the bank #5 from the A phase to the C phase.

The change module 46 then, assuming that the transformer is connected to the updated connection phase, as the same as the process performed by the analyzer 43, calculates the voltage for each phase at each node of the power distribution system. More specifically, the change module 46 simulates the voltage for each phase at each node of the power distribution system if the connection phase of the transformer were changed.

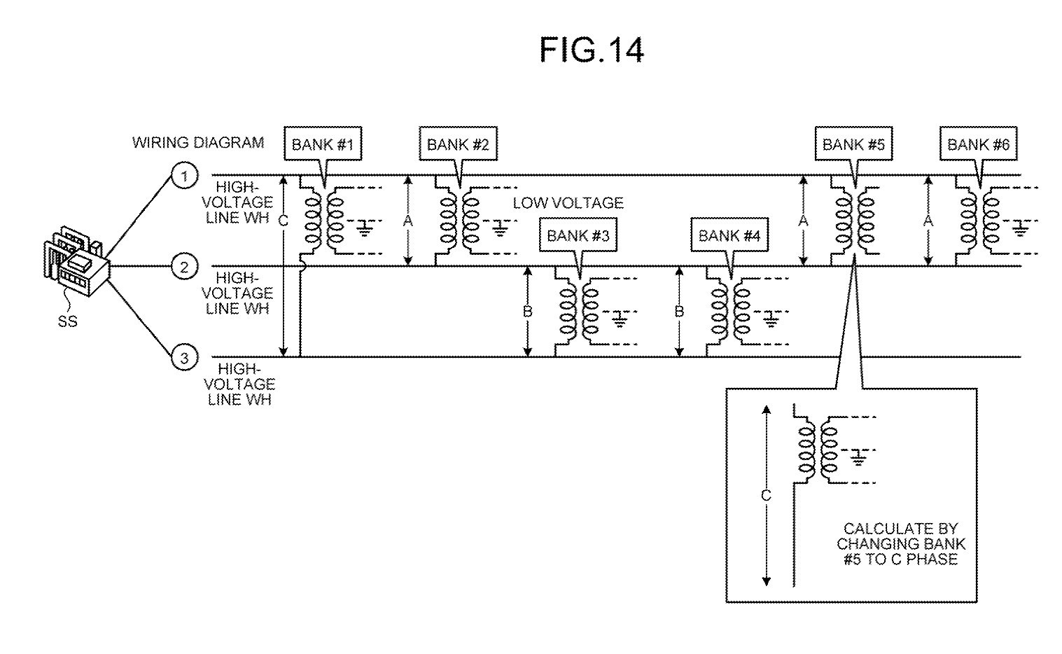

FIG. 14 is a wiring diagram schematically illustrating the connection state of the banks #1 to #6 to the high-voltage line. More specifically, the change module 46, as illustrated in FIG. 14, changes the connection phase of the bank #5 from the A phase to the C phase and calculates the voltage for each phase at each node of the power distribution system. For example, the change module 46 calculates the voltage for each phase at the nodes that connect the high-voltage line WH of the power distribution system and the banks #1 to #6.

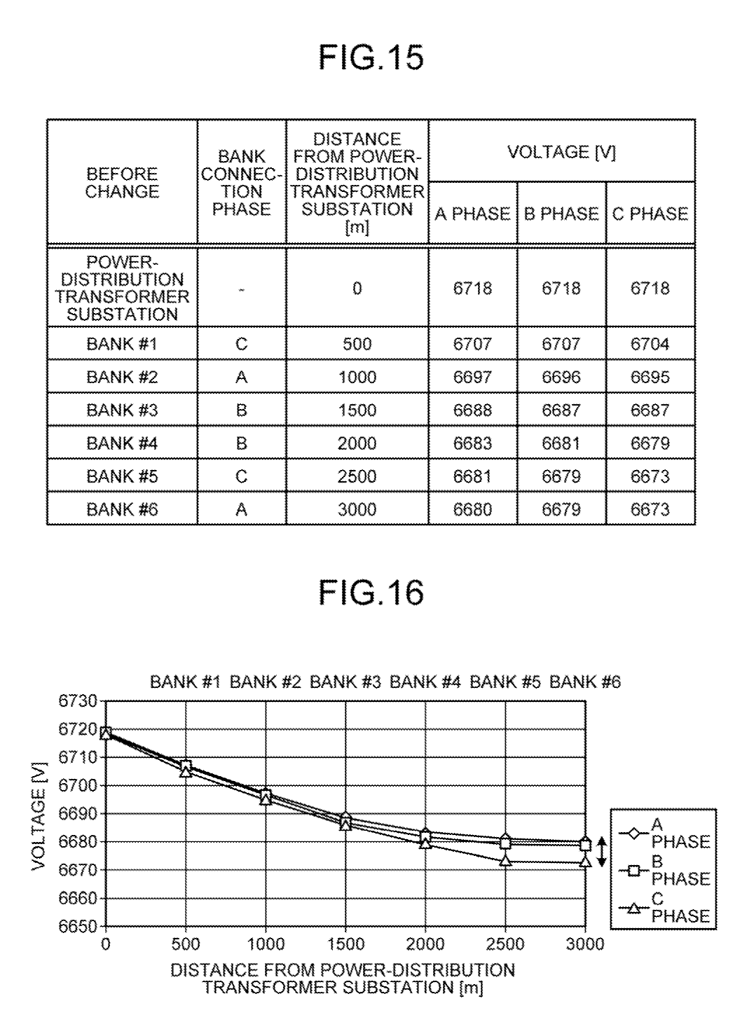

FIG. 15 is a table illustrating one example of the voltages of the respective phases of the high-voltage line at the power-distribution substation and the banks #1 to #6. In the example in FIG. 15, illustrated are the results of calculated voltages of the respective phases at the power-distribution substation SS and the banks #1 to #6, with the change in the connection phase of the bank #5 from the A phase to the C phase. In the example in FIG. 15, as the same as those in FIG. 11, the connection phases of the banks #1 to #6 are further indicated. Moreover, in the example in FIG. 15, as the same as those in FIG. 11, the distances from the power-distribution substation SS to the banks #1 to #6 are indicated.

The change module 46 generates and outputs to the client terminal 11 the image information of a screen that displays the calculated voltage values of the respective phases of the power distribution system as a graph.

FIG. 16 is a graph illustrating one example of the voltage values of the respective phases in the power distribution system. In the example in FIG. 16, illustrated are the voltage values of the respective phases at the connection points of the banks #1 to #6 in the power distribution system, and as compared with those in FIG. 12, the difference in the voltage values among the respective phases is reduced. This enables the staff member of the power distribution sector to understand the situation of the voltages of the respective phases at the time the connection phase of the transformer were changed, and to determine whether the connection phase has to be changed.

As for the controller 24, various types of integrated circuits and electronic circuits can be employed. Furthermore, a part of the functional modules of the controller 24 can be made as a separate integrated circuit or electronic circuit. For example, the integrated circuit includes an application specific integrated circuit (ASIC). The electronic circuit includes a central processing unit (CPU) and a micro processing unit (MPU).

Sequence of Processing

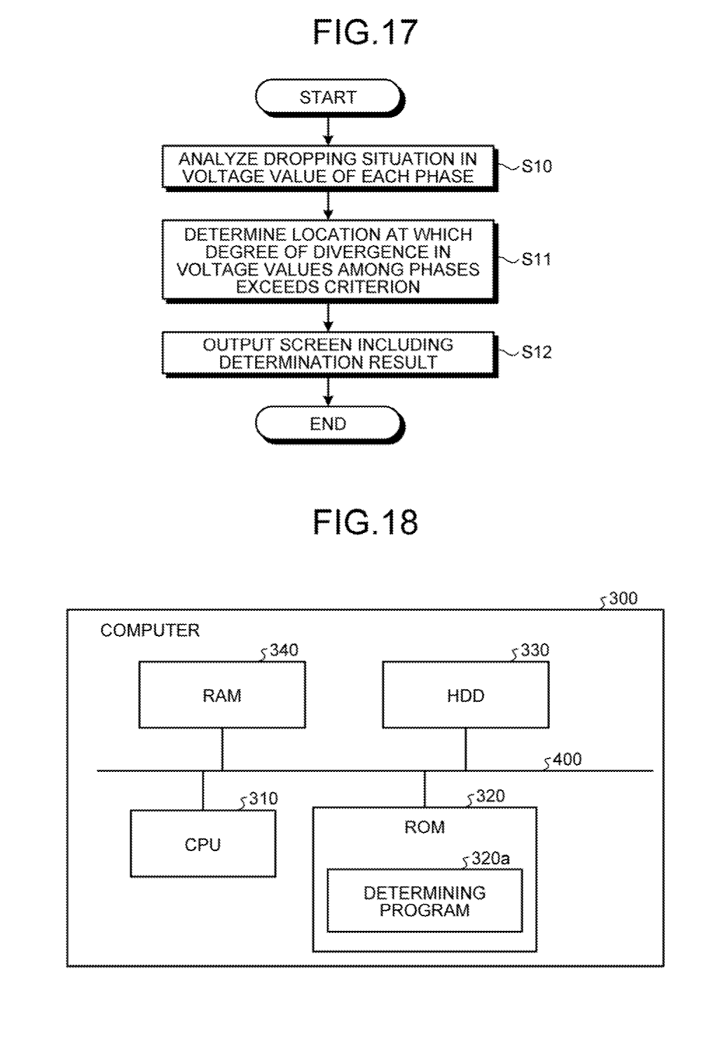

The following describes the sequence of a determining process in which the determining apparatus 10 determines the occurrence of imbalance according to the first embodiment. FIG. 17 is a flowchart illustrating a procedure for the determining process. In the determining process, the process is started at a given timing, for example, the timing of the determination instructed from the client terminal 11.

As illustrated in FIG. 17, the analyzer 43 calculates, assuming that the transformers are connected to the connection phases indicated in the connection phase information 33, the voltage for each phase at each node of the power distribution system and analyzes the fluctuation situations in the voltage values of the respective phases (Step S10). The second determining module 44 determines, from the voltage value of each phase at each node in the power distribution system calculated by the analyzer 43, whether any location at which the degree of divergence in the voltage values among the phases exceeds a given criterion is present for each node (Step S11). The output module 45 generates and outputs to the client terminal 11 the image information of a screen including the result of determination by the second determining module 44 (Step S12) to display the screen on the client terminal 11, and the process is then ended. In addition, the output module 45 may identify and output the transformer corresponding to the location at which the criterion is exceeded.

Effects of First Embodiment

As in the foregoing, the determining apparatus 10 analyzes the fluctuation situations of voltage values of the respective phases in the power distribution line using a three-phase three-wire system. The determining apparatus 10 then determines whether any location at which the degree of divergence in the voltage values among the phases exceeds a given criterion is present. Then, the determining apparatus 10 outputs the result of determination. Consequently, the determining apparatus 10 enables identification of the occurrence of imbalance. The determining apparatus 10 further enables identification of the occurrences of imbalance in chronological order.

Furthermore, the determining apparatus 10 defines the location at which whether the criterion is exceeded is determined, as the installation location of a transformer. Consequently, the determining apparatus 10 enables identification of the installation location of which transformer the imbalance is occurring at.

The determining apparatus 10 further analyzes the fluctuation situation of the voltage value of each phase in the power distribution line using a three-phase three-wire system, from the voltage value of any of the phases in the three-phase three-wire system by using the voltage value of the transformer. The determining apparatus 10 then determines whether any location at which the degree of divergence in the voltage values among the phases exceeds a given criterion is present, and if the location is present, the determining apparatus 10 identifies and outputs the transformer corresponding to the location. Thus, the determining apparatus 10, which analyzes the voltage value of any of the phases in the three-phase three-wire system from the voltage value of any of the phases in the three-phase three-wire system in this manner, can accurately analyze the voltage values of the phases in the three-phase three-wire system, and can accurately acquire the occurrence of imbalance.

Moreover, when the location at which the criterion is exceeded is between two neighboring transformers, the determining apparatus 10 identifies and outputs either one of the two transformers as the transformer corresponding to the location. Consequently, the determining apparatus 10 enables identification of the transformer for which the connection phase has to be changed to relieve the imbalance.

The determining apparatus 10 further creates a graph that represents the fluctuation situations of the voltages by arranging the voltage values of the transformers in the order of distance from the power transmission source. Consequently, the determining apparatus 10 enables identification of the fluctuation situation of the voltage of each phase according to the distance.

The determining apparatus 10 further calculates the voltage for each phase at each node of the power distribution system if the connection phase of the transformer were changed. This enables identification of the fluctuation situations of the voltages of the respective phases according to the distance at the time the connection phase were changed.

### [b] Second Embodiment

While the embodiment of the disclosed apparatus has been described above, the present invention may be embodied in various different embodiments other than the above-described embodiment. In the following description, other embodiments that fall within the scope of the invention will be illustrated.

For example, in the above-described first embodiment, the screen including the location at which the degree of divergence in the voltage values among the phases exceeds the given criterion is exemplified to be output to the client terminal 11. The disclosed apparatus, however, is not limited to this. For example, the information concerning the location at which the degree of divergence in the voltage values among the phases exceeds the given criterion may be output to a system that manages the maintenance of the power distribution system. When the location at which the criterion is first exceeded is between two transformers, for example, the information concerning either one of the two transformers may be output to the system that manages the maintenance as the information of the transformer that needs a change in the connection phase.

Distribution and Integration

The respective constituent elements of the devices and apparatuses illustrated in the drawings are functionally conceptual and are not necessarily needed to be configured physically as illustrated in the drawings. In other words, the specific embodiments of distribution or integration of the devices and apparatuses are not limited to those illustrated, and the whole or a part thereof can be configured by being functionally or physically distributed or integrated in any unit according to various types of loads and usage. For example, the acquiring module 40, the identifying module 41, the first determining module 42, the analyzer 43, the second determining module 44, the output module 45, and the change module 46 in the first embodiment may be connected via a network as an external device of the determining apparatus 10. Furthermore, the acquiring module 40, the identifying module 41, the first determining module 42, the analyzer 43, the second determining module 44, the output module 45, and the change module 46 may be implemented in separate devices and connected via a network to coordinate so as to achieve the functions of the above-described determining apparatus 10.

Determining Program

The various processes described in the foregoing embodiments can be implemented by executing a program prepared in advance on a computer such as a personal computer and a workstation. In the following description, one example of a computer that executes a determining program which renders the same functions as those in the above-described embodiments will be explained with reference to FIG. 17. FIG. 17 is a block diagram illustrating one example of the computer that executes the determining program.

As illustrated in FIG. 17, a computer 300 includes a central processing unit (CPU) 310, a read only memory (ROM) 320, a hard disk drive (HDD) 330, and a random access memory (RAM) 340. The foregoing various modules 310 to 340 are connected via a bus 400.

In the ROM 320, stored in advance is a determining program 320a that exercises the same functions as those of the various modules in the embodiments. For example, stored therein is the determining program 320a that exercises the same functions as those of the acquiring module 40, the identifying module 41, the first determining module 42, the analyzer 43, the second determining module 44, the output module 45, and the change module 46 in the embodiments. The determining program 320a may be divided as appropriate.

The CPU 310 then reads out and executes the determining program 320a from the ROM 320 to perform the same operation as those in the foregoing embodiments. More specifically, the determining program 320a performs the same operation as those of the acquiring module 40, the identifying module 41, the first determining module 42, the analyzer 43, the second determining module 44, the output module 45, and the change module 46.

The determining program 320a is not necessarily needed to be stored in the ROM 320 from the beginning. The determining program 320a may be stored in the HDD 330.

For example, the program is kept stored in a “transportable physical medium” that is inserted to the computer 300 such as a flexible disk (FD), a CD-ROM, a DVD disc, a magneto-optical disk, and an IC card. The computer 300 may then read out and execute the program from the foregoing.

Furthermore, the program is kept stored in “other computers (or servers)” connected to the computer 300 via a public line, the Internet, a LAN, a WAN, or the like. The computer 300 may then read out and execute the program from the foregoing.

The occurrence of imbalance can be identified.

All examples and conditional language recited herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A non-transitory computer-readable recording medium having stored therein a program that causes a computer to execute an imbalance determining process comprising:
analyzing fluctuation situations of voltage values of respective phases in a power distribution line using a three-phase three-wire system;
determining whether a location at which degree of divergence in voltage values among the phases exceeds a predetermined criterion is present; and
outputting a result of the determining.

2. The non-transitory computer-readable recording medium according to claim 1, wherein the location is an installation location of a transformer.

3. The non-transitory computer-readable recording medium according to claim 2, wherein:
the analyzing includes analyzing the fluctuation situations of voltage values of respective phases in a power distribution line using a three-phase three-wire system, from a voltage value of any of the phases in the three-phase three-wire system by using a voltage value of the transformer;
the determining includes determining whether a location at which the degree of divergence in voltage values among the phases exceeds the predetermined criterion is present; and
the outputting includes identifying and outputting a transformer corresponding to the location when the location is present.

4. The non-transitory computer-readable recording medium according to claim 3, wherein either one of two neighboring transformers is identified and output as a transformer corresponding to the location when the location is between the two neighboring transformers.

5. The non-transitory computer-readable recording medium according to claim 1, wherein the imbalance determining process further includes creating a graph that represents fluctuation situations of voltages by arranging voltage values of a primary side of transformers in an order of distance or an order of connection from a power transmission source.

6. An imbalance determining method comprising:
analyzing fluctuation situations of voltage values of respective phases in a power distribution line using a three-phase three-wire system, using a processor;
determining whether a location at which degree of divergence in voltage values among the phases exceeds a predetermined criterion is present, using the processor; and
outputting a result of the determining, using the processor.

7. An imbalance determining apparatus comprising:
a memory; and
a processor coupled to the memory, wherein the processor executes a process including:
analyzing fluctuation situations of voltage values of respective phases in a power distribution line using a three-phase three-wire system;
determining whether a location at which degree of divergence in voltage values among the phases exceeds a predetermined criterion is present from results of analyses at the analyzing; and
outputting a result of determination made at the determining.
